(19) United States
(12) Patent Application Publication
(10) Pub. No.: US 2017/0246844 A1
(43) Pub. Date: Aug. 31, 2017

(54) CHIP CARD SUBSTRATE AND METHOD OF FORMING A CHIP CARD SUBSTRATE

(71) Applicant: Infineon Technologies AG, Neubiberg (DE)

(72) Inventors: Siegfried HOFFNER, Nesselwang (DE); Mohammed Reza HUSSEIN, Regensburg (DE); Frank PUESCHNER, Kelheim (DE); Birgit BINDER, Straubing (DE)

(21) Appl. No.: 15/593,361

(22) Filed: May 12, 2017

Related U.S. Application Data
(62) Division of application No. 14/243,946, filed on Apr. 3, 2014.

(51) Int. Cl. B32B 27/08; B32B 3/26; B32B 3/02; B32B 7/12; B32B 27/36; B32B 27/30; B32B 7/04; B32B 37/00; B32B 37/18; B32B 38/04; B29C 65/48; H01L 23/14; H01L 23/498; H01L 21/48; G06K 19/077

(52) U.S. Cl. CPC B32B 27/08; G06K 19/07749; B32B 3/266; B32B 3/02; B32B 7/12; B32B 27/365; B32B 27/304; B32B 7/045; B32B 37/0084; B32B 37/185; B32B 38/04; B29C 65/48; H01L 23/145; H01L 23/49855; H01L 21/4803; B32B 2038/047; B32B 2250/03; B32B 2250/24; B32B 2305/38; B32B 2327/06; B32B 2367/00; B32B 2369/00; B32B 2425/00; B29K 2627/06

(57) ABSTRACT

A chip card substrate is provided, which includes a plurality of layers. The plurality of layers includes a first polymer layer including a first polymer material, a second polymer layer disposed over the first polymer layer and a second polymer material different from the first polymer material. The plurality of layers further includes a third polymer layer disposed over the second polymer layer and including the first polymer material. The second polymer layer includes a plurality of cutouts at an edge of the second polymer layer so that the first polymer material of the first polymer layer and of the third polymer layer form a coupling through the plurality of cutouts.

### CROSS REFERENCE TO RELATED APPLICATION

This application is a Divisional Application and claims priority to U.S. application Ser. No. 14/243,946 filed on Apr. 3, 2014, which is incorporated by reference herein in its entirety.

### TECHNICAL FIELD

Various embodiments relate generally to a chip card substrate and to a method of forming a chip card substrate.

### BACKGROUND

In general, an integrated circuit or a chip may be included in or on a chip card substrate usually made of plastic material, thereby forming a so-called smart card (in the following also referred to as chip card or as integrated circuit card). There may be various applications including for example personal identification or banking applications. A chip card typically includes a contact pad structure for electrically connecting the chip card to an external device, e.g. to a card reader. Among the different types of smart cards, there are contactless smart cards such that the card data exchange and the power supply of the card may be realized using induction technology, e.g. radio frequency. A so-called dual interface card may include both, the contact pad structure and the contactless interface. The chip card or the chip card substrate, respectively, usually include a plurality of layers. Technical requirements for the chip card or the chip card substrate typically include that adhesive forces joining the plurality of layers may be high enough to prevent peeling of the layers, even if the chip card is subjected to external forces, chemical substances, temperature variations, etc.

### SUMMARY

A polymer sheet for a plurality of chip card substrates is provided, which includes a plurality of layers. The plurality of layers includes a plurality of first polymer layers including a first polymer material, a plurality of second polymer layers disposed over the plurality of first polymer layers and a second polymer material different from the first polymer material. The plurality of layers further includes a plurality of third polymer layers disposed over the second polymer layers and including the first polymer material. The second polymer layers include a plurality of cutouts at an edge of the second polymer layers so that the first polymer material of the first polymer layers and of the third polymer layers form a coupling through the plurality of cutouts.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A and FIG. 1B show cross sectional views of a chip card substrate according to various embodiments;

FIG. 2A and FIG. 2B show schematic top views of a chip card substrate according to various embodiments, and FIG. 2C and FIG. 2D show cross sectional views of the chip chard substrate of FIG. 2B along a line B-B′ according to various embodiments;

FIG. 3A, FIG. 3B, FIG. 3C and FIG. 3D each show a top view of an antenna carrier according to various embodiments;

FIG. 4 shows a top view of a sheet of antenna carriers according to various embodiments;

FIG. 5A shows a top view of a chip card according to various embodiments, and FIG. 5B shows a cross sectional view of the chip card of FIG. 5A along a line C-C′;

FIG. 6 shows a process flow for a method of forming a chip card substrate.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Dimensions of layers described herein may be specified by their dimensions in three orthogonal directions, with the dimension in which the layer is substantially smaller than in the other two dimensions being referred to as the thickness or the height of the layer. The other two dimensions extend in the plane of the layer and orthogonal to each other and to the thickness. One of the other two dimensions extending parallel to a longer edge of the layer may be referred to as the length of the layer. The other dimension, which may extend parallel to a shorter edge of the layer, may be referred to as the width of the layer.

The terms surface, main surface, side or main side of a layer, a chip card substrate or a chip card, unless specified differently, may refer to sides or surfaces of the layer, the chip card substrate or the chip card extending along the length and the width direction. In other words, those terms refer to the sides, in other words surfaces, of the layer, in other words substrate, e.g. a card, that cover substantially more area than edges connecting the two sides, in other words surfaces.

A chip card substrate and/or a chip card may include or consist of polymer materials. The chip card and/or the chip card substrate may form a layer stack including a plurality of layers, and each layer may include polymer material. In various embodiments, the chip card and/or the chip card substrate may include layers that each include or essentially consist of the same polymer material. In this way, during a lamination process that may for example include heating and/or pressurizing the layers, the layers may soften and join more or less seamlessly to form a monolithically integrated structure. In other words, if the layers essentially consist of the same material, a monolithically integrated structure including a plurality of layers may be formed during the lamination process. The monolithically integrated structure may form a strong, durable connection between the layers.

The dual interface card may include an antenna. The antenna may be provided over or on an antenna carrier. The antenna may be formed by means of forming a metal layer over the substrate and etching the metal layer. In that case, the antenna carrier may include or essentially consist of polyethylene terephthalate (PET). Further layers of the chip card substrate may include or essentially consist of different polymer materials, for example polyvinyl chloride (PVC) or polycarbonate (PCB). The difference in materials may prevent a monolithic structure from forming, and it may furthermore prevent that the PET and the PVC and/or PCB join at all.

An adhesive may be disposed between the PET layer and the PVC layer or between the PET layer and the PCB layer. However, only few adhesives may be suitable for gluing PET, and even fewer may be suitable for gluing PET to PVC and/or PCB. An adhesive force of the adhesive exerted on the PET and the PVC and/or the PCB, respectively, may be so weak that the layer stack delaminates. If the chip card substrate was tested for its durability, it might fail. Furthermore, the additional layer of adhesive and the costs associated with the formation thereof may increase the total manufacturing costs.

In various embodiments, a chip card substrate with improved resilience to delamination/disintegration and low production costs may be provided.

In various embodiments, the antenna carrier may include a plurality of cutouts along its edge as compared with a top layer and a bottom layer of a chip card substrate. Lamination of the chip card substrate may thus form a monolithically integrated structure of the top layer and the bottom layer through the cutouts. In various embodiments, the adhesive forces along the edge of the antenna carrier may be improved, at least in the cutouts. The chip card substrate may be more resilient to delamination and may thus pass durability tests.

In various embodiments, the cutouts may be formed during a manufacture of the antenna carrier. An end user may use the antenna carrier and integrate it monolithically during the lamination process performed by an existing manufacturing facility, without a necessity to introduce additional processes.

In various embodiments, a chip card substrate may be provided. The chip card substrate may include a plurality of layers including a first polymer layer having a first polymer material, a second polymer layer disposed over the first polymer layer and including a second polymer material different from the first polymer material. The plurality of layers may further include a third polymer layer disposed over the second polymer layer and including the first polymer material. The second polymer layer may include a plurality of cutouts at an edge of the second polymer layer so that the first polymer material of the first polymer layer and of the third polymer layer form a mechanical coupling through the plurality of cutouts.

In various embodiments, the mechanical coupling may include a monolithic structure of the first polymer material.

In various embodiments, the second polymer material may include polyethylene terephthalate.

In various embodiments, the first polymer material may include polycarbonate.

In various embodiments, the first polymer material may include polyvinyl chloride.

In various embodiments, the first polymer layer and the third polymer layer may be rectangular.

In various embodiments, the cutouts in the second polymer layer may be arranged such that the first polymer layer and the third polymer layer form the, e.g. mechanical, coupling at least at their respective four corners.

In various embodiments, the second polymer layer may include an antenna.

In various embodiments, the antenna may include aluminum.

In various embodiments, the second polymer layer may include a plurality of layers.

In various embodiments, the chip card substrate may be included in a chip card, wherein the chip card may further include a chip.

In various embodiments, a polymer sheet for a plurality of chip card substrates may be provided. The polymer sheet may include a plurality of second polymer layers arranged in a two-dimensional array in a plane of the polymer sheet, and a plurality of cutouts. The plurality of cutouts is arranged at edges of the plurality of second polymer layers.

In various embodiments, the plurality of second polymer layers may include polyethylene terephthalate.

In various embodiments, a method of forming a chip card substrate may be provided. The method may include forming a plurality of cutouts at an edge of a second polymer layer, arranging a first polymer layer underneath the second polymer layer, arranging a third polymer layer above the second polymer layer, and forming a coupling, e.g. mechanical coupling, of the first polymer layer and the third polymer layer through the plurality of cutouts.

In various embodiments, the forming a coupling may include laminating.

In various embodiments, the polymer sheet may be used in a method of forming a plurality of chip card substrates. The method may include providing the polymer sheet with the plurality of cutouts, arranging a first polymer layer underneath the polymer sheet, arranging a third polymer layer above the polymer sheet, forming a coupling of the first polymer layer and the third polymer layer through the plurality of cutouts.

In various embodiments, the method may further include singulating the coupled polymer layers into the plurality of chip card substrates.

In various embodiments, the singulating may include stamping.

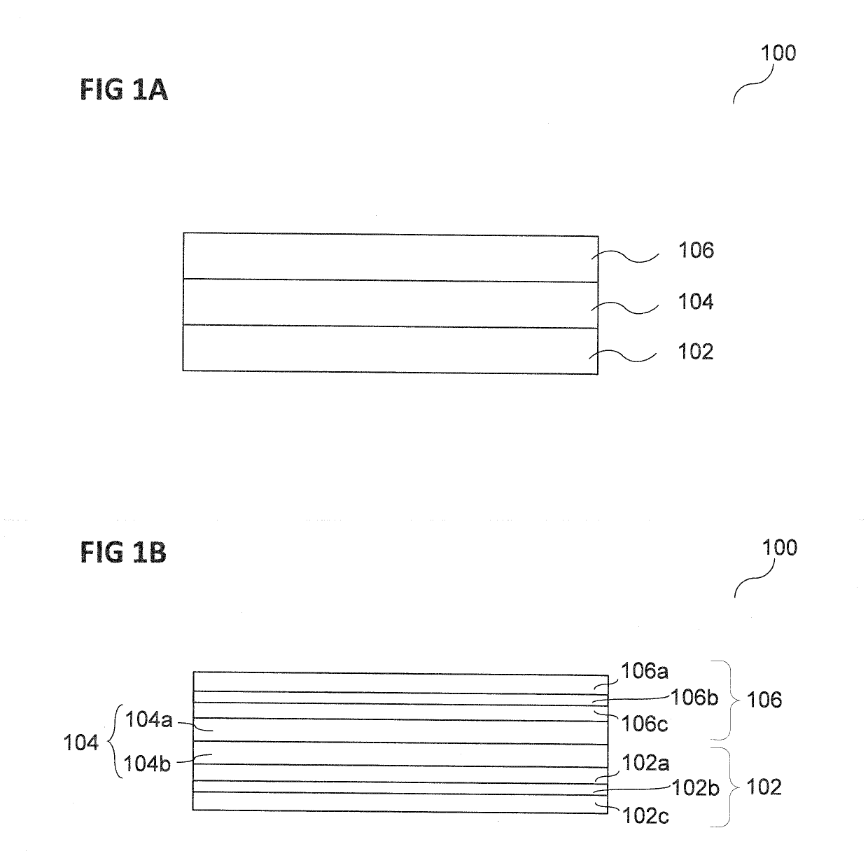

FIG. 1A and FIG. 1B show cross sectional views of a chip card substrate 100 according to various embodiments.

The chip card substrate 100 may be a part of a chip card.

As shown in FIG. 1A, the chip card substrate 100 may, in various embodiments, include a first polymer layer 102, also referred to as a bottom polymer layer 102 or a bottom layer 102, a second polymer layer 104, also referred to as an antenna carrier 104 or a middle layer 104, and a third polymer layer 106, also referred to as a top polymer layer 106 or a top layer 106.

In various embodiments, the second polymer layer 104 may be disposed over the first polymer layer 102, and the third polymer layer 106 may be disposed over the second polymer layer 104.

The first polymer layer 102 may be a layer. The first polymer layer 102 may have a rectangular or quadratic shape. The first polymer layer 102 may have a substantially rectangular or quadratic shape. According to various embodiments, the first polymer layer 102 may be a quadratic film or a rectangular film having rounded corners.

In various embodiments, the first polymer layer 102 may have a length in a range from about 1 cm to about 20 cm, e.g. from about 1 cm to about 3 cm or from about 5 cm to about 10 cm, e.g. about 8.56 cm or about 6.6 cm or about 2.5 cm or about 1.5 cm.

In various embodiments, the first polymer layer 102 may have a width in a range from about 1 cm to about 10 cm, e.g. from about 1 cm to about 2 cm or from about 3 cm to about 6 cm, e.g. about 5.398 cm or about 3.3 cm or about 1.5 cm or about 1.2 cm or about 4 cm.

According to various embodiments, the first polymer layer 102 may include or may essentially consist of at least one material of the following group of materials: a plastic material, a thermoplastic material, a flexible material, a polymer material, a polyimide, a laminate material, or any other suitable material providing for example a flexible first polymer layer 102. In various embodiments, the first polymer layer 102 may include or essentially consist of a substantially amorphous thermoplastic, for example polyvinyl chloride or poly carbonate.

According to various embodiments, the first polymer layer 102 may have a thickness in a range from about 10 μm to about 1 mm, e.g. in the range from about 10 μm to about 200 μm, e.g. in the range from about 10 μm to about 100 μm, e.g. in the range from about 50 μm, e.g. a thickness larger than 50 μm or smaller than 50 μm. The first polymer layer 102 may be a foil 102, e.g. a polymer foil 102.

In various embodiments, the first polymer layer 102 may include or essentially consist of a single layer. In various embodiments, as shown in FIG. 1B, the first polymer layer 102 may include or essentially consist of a plurality of layers 102a, 102b, 102c, . . . , 102z, for example a layer stack 102 including or essentially consisting of the plurality of layers 102a, 102b, 102c, . . . , 102z. “a” and “z” may denote a first layer and a last layer of the layer stack 102. In other words, 102a may be at one end of the layer stack 102, and 102z may be at an opposite end of the layer stack 102.

Each layer of the plurality of layers 102a, 102b, 102c, . . . , 102z may have a thickness that is a fraction up to unity of the thickness of the first layer 102. A sum of the thicknesses of the plurality of layers 102a, 102b, 102c, . . . , 102z may be the thickness of the first layer 102. In various embodiments, at least one layer of the plurality of layers 102a, 102b, 102c, . . . , 102z may have the length and the width of the chip card substrate and/or the chip card. In various embodiments, one or more layers of the plurality of layers 102a, 102b, 102c, . . . , 102z may be shorter than the length of the chip card substrate and/or the chip card. In various embodiments, one or more layers of the plurality of layers 102a, 102b, 102c, . . . , 102z may be less wide than the width of the chip card substrate and/or the chip card. In other words, in various embodiments, at least one layer 102a, 102b, 102c, . . . , 102z may have a length and/or a width that is different from the length and/or the width, respectively. In various embodiments, all layers 102a, 102b, 102c, . . . , 102z may have the same length and/or the same width.

The first polymer layer 102 may include more than one type of material. In various embodiments, the layer stack 102 may include a layer 102a, . . . , 102z of a first material and another layer 102a, . . . , 102z of a second material. In various embodiments, the first polymer layer 102 may for example include a (pure) metal layer 102a, . . . , 102z or a metal alloy layer 102a, . . . , 102z and a polymer layer 102a, . . . , 102z. By way of example, one of the layers 102a, . . . , 102z may, partially or completely, include or essentially consist of the metal or the metal alloy. The layer 102a, . . . , 102z may for example include a metal shielding structure for protecting parts/regions of the chip card from electromagnetic radiation. In various embodiments, the second polymer layer 104 may include a paper layer. In various embodiments, the second polymer layer 104 may include a capacitor structure. In various embodiments, different layers 102a, . . . , 102z may include different structures, e.g. layers 102a, 102c and 102e may include or essentially consist of polycarbonate layers, layer 102b may include a shielding structure, and layer 102d may include a capacitor structure.

In various embodiments, the first polymer layer 102 may for example include at least one contact pad, e.g. two contact pads, e.g. three contact pads, e.g. four contact pads, e.g. five contact pads, e.g. six contact pads, e.g. seven contact pads, e.g. eight contact pads, e.g. nine contact pads, e.g. ten contact pads, or even more than ten contact pads. The contact pads may be exposed on one or both main surfaces of the first polymer layer 102. The contact pads may be arranged in accordance with the standard ISO 7816.

The second polymer layer 104, as shown in FIG. 1A, may be a layer. The second polymer layer 104 may have a substantially rectangular or quadratic shape. In various embodiments, the second polymer layer 104 may have a length in a range from about 1 cm to about 20 cm, e.g. from about 1 cm to about 3 cm or from about 5 cm to about 10 cm, e.g. about 8.56 cm or about 6.6 cm or about 2.5 cm or about 1.5 cm.

In various embodiments, the second polymer layer 104 may have a width in a range from about 1 cm to about 10 cm, e.g. from about 1 cm to about 2 cm or from about 3 cm to about 6 cm, e.g. about 5.398 cm or about 3.3 cm or about 1.5 cm or about 1.2 cm or about 4 cm.

According to various embodiments, the second polymer layer 104 may include or may essentially consist of a material that is different from the material of the first polymer layer 102 and different from the material of the third polymer layer 106. The material of the second polymer layer 104 may include or essentially consist of at least one material of the following group of materials: a plastic material, a thermoplastic material, a flexible material, a polymer material, a polyimide, a laminate material, or any other material that is suitable for disposing, for example by means of etching or printing, an antenna on. In various embodiments, the second polymer layer 104 may include or essentially consist of polyethylene terephthalate (PET).

According to various embodiments, the second polymer layer 104 may have a thickness in a range from about 10 μm to about 1 mm, e.g. in the range from about 10 μm to about 200 μm, e.g. in the range from about 10 μm to about 100 μm, e.g. about 36 μm. The second polymer layer 104 may be a foil 104, e.g. a polymer foil 104.

In various embodiments, as shown in FIG. 1B, the second polymer layer 104 may include or essentially consist of a single layer. In various embodiments, the second polymer layer 104 may include or essentially consist of a plurality of layers 104a, 104b, 104c, . . . , 104z, for example a layer stack 104 including or consisting of the plurality of layers 104a, 104b, 104c, . . . , 104z. “a” and “z” may denote a first layer and a last layer of the layer stack 104. In other words, 104a may be at one end of the layer stack 104, and 104z may be at an opposite end of the layer stack 104.

Each layer of the plurality of layers 104a, 104b, 104c, . . . , 104z may have a thickness that is a fraction up to unity of the thickness of the second layer 104. In various embodiments, a sum of the thicknesses of the layers 104a, 104b, 104c, . . . , 104z may be the thickness of the second layer 104. In various embodiments, at least one layer of the plurality of layers 104a, 104b, 104c, . . . , 104z may have the length of the chip card substrate and/or the chip card and the width of the chip card substrate and/or the chip card. In various embodiments, one or more layers of the plurality of layers 104a, 104b, 104c, . . . , 104z may be shorter than the length of the chip card substrate and/or the chip card. In various embodiments, one or more layers of the plurality of layers 104a, 104b, 104c, . . . , 104z may be less wide than the width of the chip card substrate and/or the chip card. In other words, in various embodiments, at least one layer 104a, 104b, 104c, . . . , 104z may have a length and/or a width that is different from the length and/or the width of the chip card substrate and/or the chip card, respectively. In various embodiments, all layers 104a, 104b, 104c, . . . , 104z may have the same length and/or the same width.

The second polymer layer 104 may include more than one type of material. In various embodiments, the layer stack 104 may for example include a layer 104a, 104b, 104c, . . . , 104z of one material and another layer 104a, 104b, 104c, . . . , 104z of a different material. In various embodiments, at least the material of one of the layers 104a, . . . , 104z may be different from all materials of the first polymer layer 102 and from all materials of the third polymer layer 106. The layer stack 104 may include a metal layer 104a, 104b, 104c, . . . , 104z or a metal alloy layer 104a, 104b, 104c, . . . , 104z and a polymer layer 104a, 104b, 104c, . . . , 104z. By way of example, one of the layers 104a, 104b, 104c, . . . , 104z may include a metal, e.g. a pure metal, or a metal alloy. The layer 104a, 104b, 104c, . . . , 104z may for example include an antenna. The second polymer layer 104 may for example include at least one contact pad, e.g. two contact pads, e.g. three contact pads, e.g. four contact pads, e.g. five contact pads, e.g. six contact pads, e.g. seven contact pads, e.g. eight contact pads, e.g. nine contact pads, e.g. ten contact pads, or even more than ten contact pads. The contact pads may be electrically conductively connected to the antenna. In various embodiments, at least one of the layers 104a, . . . , 104z may for example include a metal shielding structure for protecting parts/regions of the chip card from electromagnetic radiation. In various embodiments, the second polymer layer 104 may include a paper layer. In various embodiments, the second polymer layer 104 may include a capacitor structure. In various embodiments, different layers 104a, . . . , 104z may include different structures, e.g. layers 104a and 104c may include or essentially consist of one antenna 330 each, and layer 104b may include or essentially consist of PET.

The third polymer layer 106 may have a rectangular or quadratic shape. The third polymer layer 106 may have a substantially rectangular or quadratic shape. The third polymer layer 106 may have a rectangular or quadratic shape. According to various embodiments, the third polymer layer 106 may be a quadratic film or a rectangular film having rounded corners.

In various embodiments, the third polymer layer 106 may have a length in a range from about 1 cm to about 20 cm, e.g. from about 1 cm to about 3 cm or from about 5 cm to about 10 cm, e.g. about 8.56 cm or about 6.6 cm or about 2.5 cm or about 1.5 cm.

In various embodiments, the third polymer layer 106 may have a width in a range from about 1 cm to about 10 cm, e.g. from about 1 cm to about 2 cm or from about 3 cm to about 6 cm, e.g. about 5.398 cm or about 3.3 cm or about 1.5 cm or about 1.2 cm or about 4 cm.

In various embodiments, at least the first polymer layer 102 and the third polymer layer 106 may have a length of 8.56 cm and a width of 5.398 cm, or at least the first polymer layer 102 and the third polymer layer 106 may have a length of 6.6 cm and a width of 3.3 cm, or at least the first polymer layer 102 and the third polymer layer 106 may have a length of 2.5 cm and a width of 1.5 cm, or at least the first polymer layer 102 and the third polymer layer 106 may have a length of 1.5 cm and a width of 1.2 cm, or at least the first polymer layer 102 and the third polymer layer 106 may have a length of 6.56 cm and a width 4 cm.

In various embodiments, the chip card substrate 100, wherein the chip card substrate 100 may include the first polymer layer 102, the second polymer layer 104 and the third polymer layer 106, may have a thickness in a range from about 0.3 mm to about 2 mm, for example from about 0.5 mm to 1 mm, for example a thickness of 0.762 mm.

According to various embodiments, the third polymer layer 106 may include or may essentially consist of the same material as the first polymer layer 102. The third polymer layer 106 may include or may essentially consist of at least one material of the following group of materials: a plastic material, a thermoplastic material, a flexible material, a polymer material, a polyimide, a laminate material, or any other suitable material providing for example a flexible third polymer layer 106. In various embodiments, the third polymer layer 106 may include or essentially consist of a substantially amorphous thermoplastic, for example polyvinyl chloride or poly carbonate. If the first polymer layer 102 includes or essentially consists of polyvinyl chloride, the third polymer layer 106 may include or essentially consist of polyvinyl chloride. If the first polymer layer 102 includes or essentially consists of poly carbonate, the third polymer layer 106 may include or essentially consist of poly carbonate.

According to various embodiments, the third polymer layer 106 may have a thickness in a range from about 10 μm to about 1 mm, e.g. in the range from about 10 μm to about 200 μm, e.g. in the range from about 10 μm to about 100 μm, e.g. in the range from about 50 μm, e.g. a thickness larger than 50 μm or smaller than 50 μm. The third polymer layer 106 may be a foil 106, e.g. a polymer foil 106.

In various embodiments the third polymer layer 106, as shown in FIG. 1B, may include or consist of a single layer. In various embodiments, the third polymer layer 106 may include or consist of a plurality of layers 106a, 106b, 106c, . . . , 106z, for example a layer stack 106 including or consisting of the plurality of layers 106a, 106b, 106c, . . . , 106z. “a” and “z” may denote a first layer and a last layer of the layer stack 106. In other words, 106a may be at one end of the layer stack 106, and 106z may be at the other end of the layer stack 106.

Each layer of the plurality of layers 106a, 106b, 106c, . . . , 106z may have a thickness that is a fraction up to unity of the thickness of the third layer 106. A sum of the thicknesses of the plurality of layers 106a, 106b, 106c, . . . , 106z may be the thickness of the third layer 106. In various embodiments, at least one layer of the plurality of layers 106a, 106b, 106c, . . . , 106z may have the length of the chip card substrate and/or the chip card and the width of the chip card substrate and/or the chip card. In various embodiments, at least one layer 106a, 106b, 106c, . . . , 106z may have a length and/or a width that is different from the length and/or the width of the chip card substrate and/or the chip card, respectively.

In various embodiments, all layers 106a, 106b, 106c, . . . , 106z may have the same length and/or the same width.

The third polymer layer 106 may include more than one type of material. In various embodiments, the layer stack 106 may include a layer 106a, . . . , 106z of a first material and another layer 106a, . . . , 106z of a second material. In various embodiments, the third polymer layer 106 may for example include a metal layer 106a, . . . , 106z or a metal alloy layer 106a, . . . , 106z and a polymer 106a, . . . , 106z. By way of example, one of the layers 106a, . . . , 106z may, partially or completely, include or essentially consist of the metal or the metal alloy. The layer 106a, . . . , 106z may for example include a metal shielding structure for protecting parts/regions of the chip card from electromagnetic radiation. In various embodiments, the third polymer layer 106 may include a paper layer. In various embodiments, the third polymer layer 106 may include a capacitor structure. In various embodiments, different layers 106a, . . . , 106z may include different structures, e.g. layers 106a, 106c and 106e may include or essentially consist of polycarbonate layers, layer 106b may include a shielding structure, and layer 106d may include a capacitor structure.

In various embodiments, the third polymer layer 106 may for example include at least one contact pad, e.g. two contact pads, e.g. three contact pads, e.g. four contact pads, e.g. five contact pads, e.g. six contact pads, e.g. seven contact pads, e.g. eight contact pads, e.g. nine contact pads, e.g. ten contact pads, or even more than ten contact pads. The contact pads may be exposed on one or both main surfaces of the third polymer layer 106.

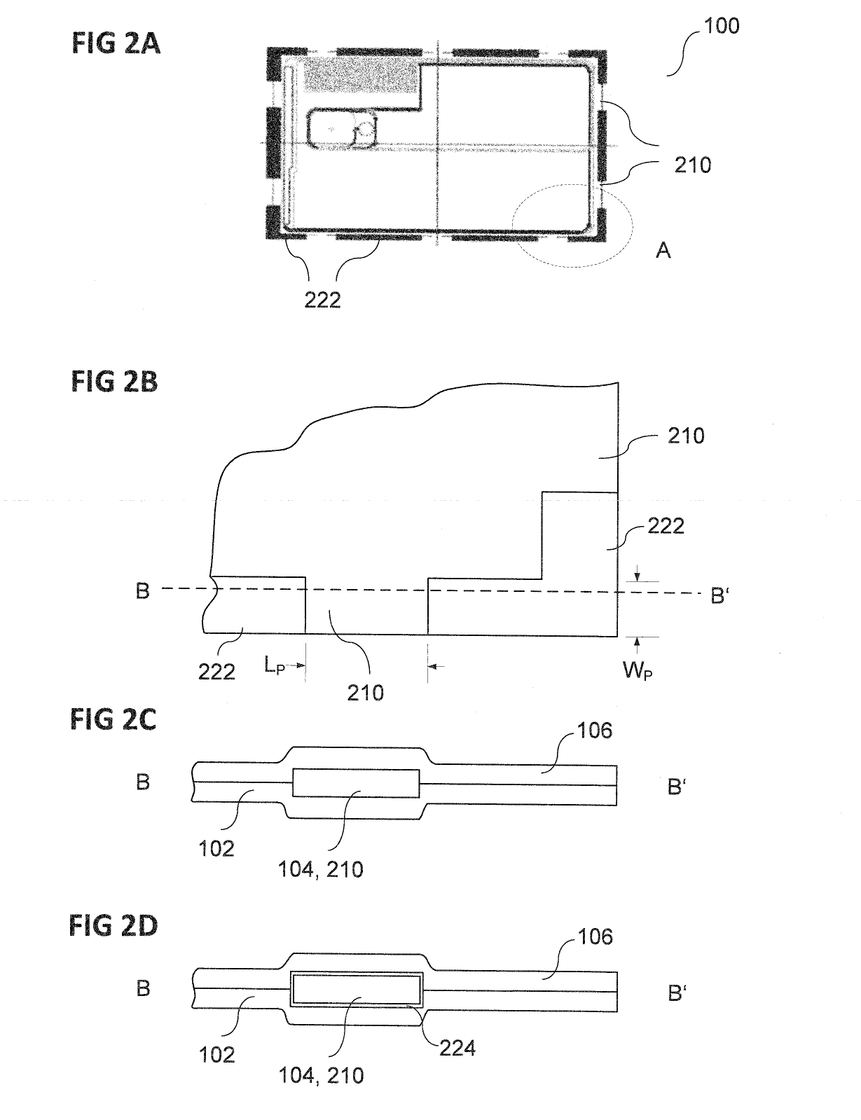

FIG. 2A and FIG. 2B show schematic top views of the chip card substrate 100 and a blowup of a region A of FIG. 2A, respectively, according to various embodiments. FIG. 2C and FIG. 2D show cross sectional views of the chip chard substrate 100 of FIG. 2B along a line B-B′ according to various embodiments

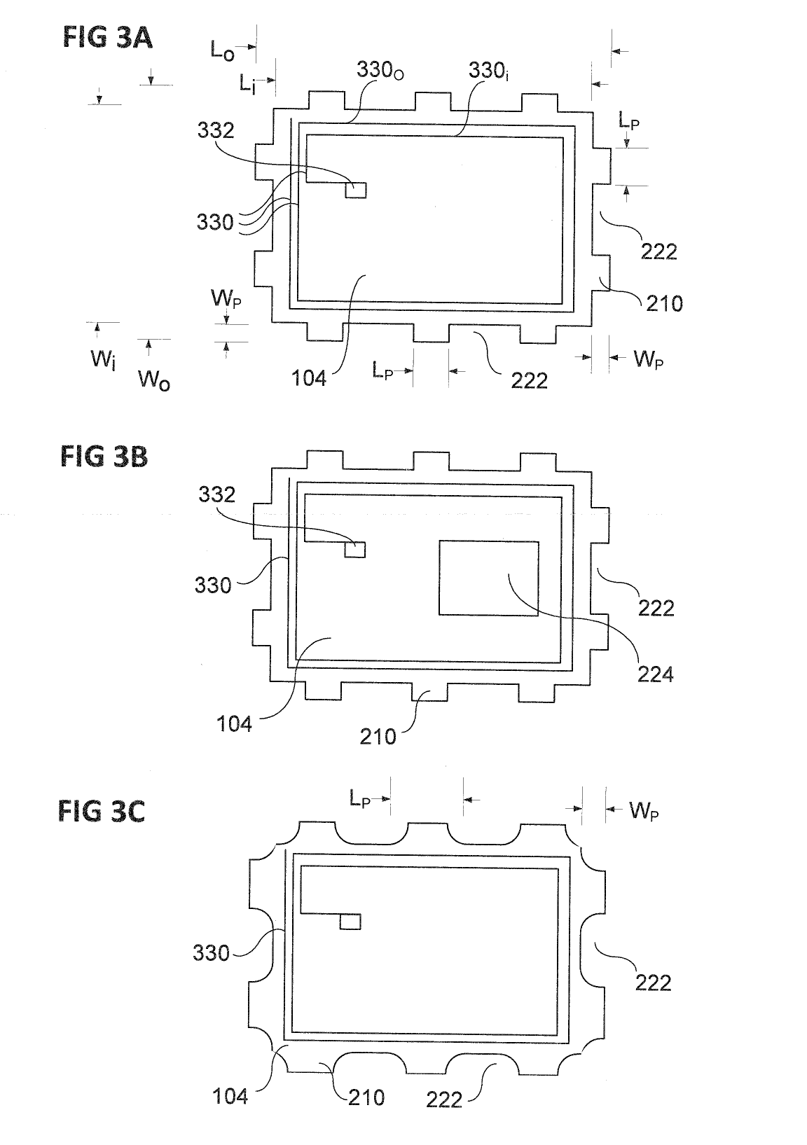

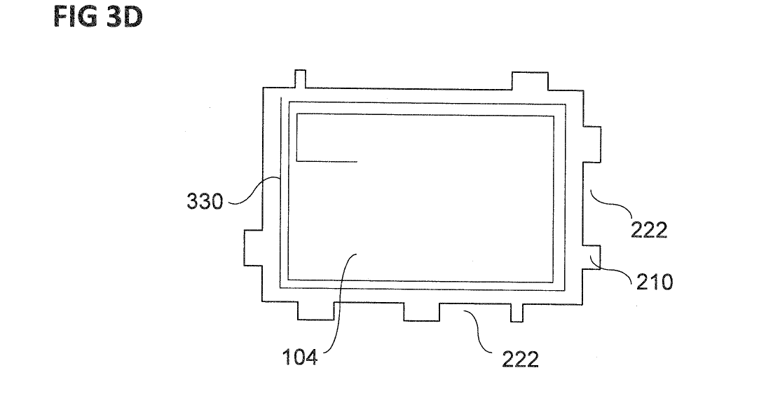

In various embodiments, as shown in FIG. 2A and FIG. 2B, the second polymer layer 104 may have a basic shape of a quadratic film or a rectangular film 104 having two sides of an outer length L_{O}, an inner length Lᵢ shorter than the outer length L_{O}, an outer width W_{O} and an inner width Wᵢ shorter than the outer width W_{O} (see FIG. 3A). Four non-smooth edges connecting the two sides may be regarded as forming two sets of four edges each. The edges formed at the inner length Lᵢ and at the inner width Wᵢ may be referred to as inner edges, and the edges formed at the outer length L_{O} and at the outer width W_{O} may be referred to as outer edges. In various embodiments, the second polymer layer 104 may include a plurality of cutouts 222 at least along its outer edge(s). The second polymer layer 104 may for example include at least one cutout 222 along each of its outer edges.

A shape of the second polymer layer 104 may alternatively be described as a basically quadratic or rectangular film 104. The two sides may have the inner length Lᵢ and the inner width Wᵢ, with a plurality of protrusions 210 projecting beyond the inner edge(s) of the square or the rectangle, for example at least one protrusion 210 projecting beyond each of the inner edges of the square or the rectangle. The protrusions 210 may project from the edge within a plane of the second polymer layer 104.

In various embodiments, a corner of the second polymer layer 104 may be formed with a cutout 222, as for example shown in FIG. 2B. In various embodiments, all corners, for example all four corners, of the second polymer layer 104 may be formed with the cutouts 222. In other words, using the description of the second polymer layer 104 as the basically rectangular or quadratic foil with the protrusions 210, a corner of the rectangular or quadratic foil may be free from the protrusions 210, and distances between corners formed on the same edge may be an inner length Lᵢ and an inner width Wᵢ. For example, all corners of the second polymer layer 104 may be free from the protrusions 210.

In various embodiments, a dimension of the protrusion 210 along the edge of the second polymer layer 104, also referred to as a length L_{P} of the protrusion 210, may be in a range from about 0.5 mm to about 1.5 mm, for example from about 0.5 mm to about 1.0 mm.

In various embodiments, a dimension of the protrusion 210 orthogonal to its length L_{P} and to the edge of the second polymer layer 104, and parallel to the plane of the second polymer layer 104, also referred to as a width W_{P} of the protrusion 210, may be in a range from about 0.5 mm to about 3 mm, for example from about 0.5 mm to about 1.0 mm.

In various embodiments, the width of the protrusion may be smaller than a distance between an outermost part of a line 330_{O} of an antenna 330 (see e.g. FIG. 3A) and the respective closest edge of the second polymer layer 104 parallel to the part of the line 330_{O} of the antenna 330. In other words, the cutouts 222 should be formed along the edge of the second polymer layer 104 in such a way that the antenna 330 is not damaged. If the cutouts 222 are formed first, the antenna 330 should be formed in such a way that it is not formed over the cutouts 222.

In various embodiments, all protrusions 210 of the second polymer layer 104 may basically have the same shape and size (length and width).

In various embodiments, as shown in FIG. 2C (and in FIG. 1A and FIG. 1B), the second polymer layer 104 may be arranged between the first polymer layer 102 and the third polymer layer 103. A length of the first polymer layer 102 may be the same as the outer length L_{O} of the second polymer layer 104. A width of the first polymer layer 102 may be the same as the outer width W_{O} of the second polymer layer 104.

In various embodiments, the first polymer layer 102 may be arranged underneath the second polymer layer 104 in such a way that the first polymer layer 102 extends also over the cutouts 222 from underneath, and the third polymer layer 106 may be arranged above the second polymer layer 104 in such a way that the third polymer layer 106 extends also over the cutouts 222 from above.

In various embodiments, the layer stack including the first polymer layer 102, the second polymer layer 104, and the third polymer layer 106 may be joined, for example by means of laminating, for example using heat and/or pressure.

In various embodiments, the first polymer layer 102 extending over the cutouts 222 from underneath and the third polymer layer 106 extending over the cutouts 222 from above may be joined through the cutouts 222 to form a monolithically integrated structure. In other words, the first polymer material of the first polymer layer 102 and the material of the third polymer layer, which may be the same material as the first polymer material, may form a coupling through the plurality of cutouts. During the coupling, for example during the lamination process, which may for example include heating and/or pressurizing the layer stack, the first polymer layer 102 and the third polymer layer 106 may soften and join more or less seamlessly to form a monolithically integrated structure. In other words, the coupling of the first polymer layer 102 and the third polymer layer 106 may include or essentially consist of a monolithically integrated structure of the first polymer material. The monolithically integrated structure may form a strong, durable connection between the first polymer layer 102 and the third polymer layer 106.

In various embodiments, the second polymer layer 104 may not soften during the coupling/lamination process, and/or the second polymer layer 104 may not join more or less seamlessly with the first polymer layer 102 and/or the third polymer layer 106 to form a monolithically integrated structure.

In various embodiments, as shown in FIG. 2D, an adhesive and/or a sealant 224 may be formed over the second polymer layer 104, i.e. between the second polymer layer 104 and the first polymer layer 102 and/or between the second polymer layer 104 and the third polymer layer 106. In various embodiments, the adhesive and/or the sealant 224 may be formed over only a part of the second polymer layer 104, i.e. between the part of the second polymer layer 104 and the first polymer layer 102 and/or between the part of the second polymer layer 104 and the third polymer layer 106, for example only over the protrusions 210. In various embodiments, foreign substances like chemicals, humidity etc. may be prevented from settling between the second polymer layer 104 and at least one of the first polymer layer 102 and the third polymer layer 106.

FIG. 3A, FIG. 3B, FIG. 3C and FIG. 3D each show a top view of an antenna carrier according to various embodiments.

As shown in FIG. 3A, in various embodiments, the protrusions 210 or the cutouts 222, respectively, may be arranged along the edges of the second polymer layer 104 in more or less regular intervals. For example, along the edge of the second polymer layer 104 that extends along its length, three protrusions 210 may be arranged, for example one protrusion each at a quarter, half and three quarters of the length of the second polymer layer 104. In the example, the respective cutouts 222 along the length of the second polymer layer 104 may be formed at the corners of the second polymer layer 104, extending almost up to a quarter of the length of the second polymer layer 104, measured from the respective corner, and from just beyond the quarter of the length of the second polymer layer 104 almost up to half the length of the second polymer layer. For example, along the edge of the second polymer layer 104 that extends along its width, two protrusions 210 may be arranged, for example one protrusion each at a one third and two thirds of the width of the second polymer layer 104. In the example, the respective cutouts 222 along the width of the second polymer layer 104 may be formed at the corners of the second polymer layer 104, extending almost up to a third of the width of the second polymer layer 104, seen from the respective corner, and from just beyond the third of the width of the second polymer layer 104 almost up to two thirds of the width of the second polymer layer 104.

In various embodiments, more or fewer protrusions 210 and cutouts 222, respectively, than shown in FIG. 3A may be formed along the edge of the second polymer layer 104 in more or less regular intervals.

In various embodiments, the antenna carrier 104 may include an antenna 330. In various embodiments, the antenna 330 may be formed on or over the antenna carrier 104. In various embodiments, the antenna 330 may be formed within the antenna carrier 104. In other words, the antenna 104, i.e. an antenna structure 104, may be formed as an intermediate layer 104x of the second polymer layer 104, with x being neither “a” nor “z”. The shape of the antenna 330 may be rectangular, e.g. square. In other words, an antenna line 330, also referred to as line 330, for example a line 330 of a conducting material, may be arranged on or over or within the antenna carrier 104. The line 330 may be arranged in a shape of a square or a rectangle.

In various embodiments, the shape of the antenna 330 may be circular, ellipsis, triangular, pentagonal or polyangular.

In various embodiments, ends of the line 330 may not join, i.e. the square, rectangle, circle, ellipse, triangle, pentagon or polygon may not be closed.

In various embodiments, the antenna 330 may include or essentially consist of a single conducting antenna line 330. In various embodiments, the line 330 may circle a circumference of the rectangle or the square more than once, for example twice or more. A corresponding multiplicity of parts of the line 330 may also be referred to as antenna tracks. In various embodiments, the multiplicity of conducting lines 330 may be adjacent to each other.

The antenna 330 may have an inside diameter, i.e. a smallest distance between an innermost part 330ᵢ, i.e. the innermost antenna track 330ᵢ of the line 330 arranged near opposite edges of the antenna carrier 104, in a range from about 2 mm to about 5 cm, e.g. from about 3 cm to about 4.5 cm, or e.g. from about 0.8 cm to about 3.5 cm.

According to various embodiments, the antenna 330 may have a width in a range from about 0.2 mm to about 5 mm, e.g. from about 0.5 mm to about 3 mm, e.g. from about 0.75 mm to about 1.5 mm, e.g. about 1 mm.

In various embodiments, the antenna 330 may have a thickness in a range of about 1 μm to about 100 μm, e.g. from about 5 μm to about 50 μm, e.g. from about 10 μm to about 20 μm, e.g. about 15 μm.

In various embodiments, the antenna 330 may be made by using aluminum or copper etch technology, so that the antenna 330 may include aluminum or copper. In various embodiments, the antenna 330 may essentially consist of a conducting material, e.g. a metal, a metal alloy, a metallic material, a metallic compound, including at least one of Cu, Al, Au, Ag, Pt, Ti, Ni, Sn, Zn, Pb, CuNi, or any non-metal electrically conducting material, e.g. graphite. In various embodiments, the antenna 330 may include a patterned layer, e.g. a patterned metal layer, e.g. a patterned copper layer (e.g. provided by using a copper etch technology). In various embodiments, the antenna 330 may be printed, for example using Ag paste.

According to various embodiments, a configuration of the antenna 330 as described before, e.g. in shape, in thickness, applied materials, applied structure may allow the antenna 330 to be flexible, such that the antenna 330 may withstand deformations if the antenna carrier 104 is bent, e.g. due to mechanical load.

According to various embodiments, the antenna 330 may be attached to the antenna carrier 104 by means of etching. The antenna 330 may also be attached to the antenna carrier 104 by means of an adhesive, soldering, molding, printing, etc.

In various embodiments, a contact pad 332 may be formed on or over the antenna carrier 104. The antenna 330 arranged on the antenna carrier 104 may have an electrically conductive connection to the at least one contact pad 332.

In various embodiments, the contact pad may be formed on the same side of the second polymer layer 104 as the antenna 330. In various embodiments, the contact pad 332 may be formed on the side of the second polymer layer 104 that the antenna 330 is not formed on. In various embodiments, the contact pad 332 may be connected to the antenna 330 by means of a via through the second polymer layer 104.

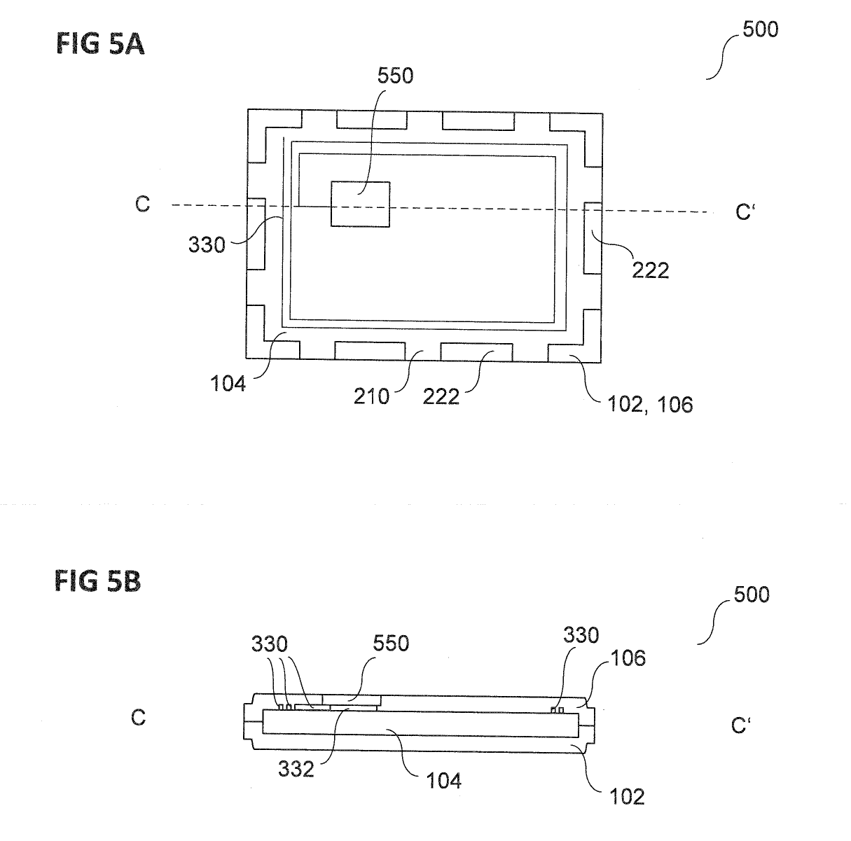

In various embodiments, a plurality of antennas 330 may be formed on or over or within the antenna carrier 104. For example, a chip card main antenna 330 and a booster antenna 330 for contactless transmission of information between a chip 550 (see FIG. 5A and/or FIG. 5B) and the chip card main antenna 330 may be provided.

In various embodiments, the antenna 330 may be attached to at least one of a front side of the antenna carrier 104 and a back side of the antenna carrier 104. The front side may be defined as the side of the antenna carrier 104 that will be facing towards the chip 550, if and when the chip will be mounted. The back side may be defined as the side of the second polymer layer 104 opposite the front side of the second polymer layer 104.

If the plurality of antennas 330 is formed, the antennas 330 may be formed on both sides of the antenna carrier 104, or all the antennas 330 may be formed on the same side of the antenna carrier 104.

In various embodiments, as shown in FIG. 3B, the second polymer layer 104 may additionally have one or more cutouts 224 in regions other than along its edges. Otherwise, features, materials, dimensions etc. may be similar to those described in connection with FIG. 3A.

The cutouts 224 may have any shape and location that does not interfere with the intended use of a chip card into which the antenna carrier 104 is to be integrated. For example, the antenna(s) 330 and the contact pad 332 should not be damaged when the cutouts 224 are formed, or the antenna(s) 330 and the contact pad 332 should not be formed over the cutouts 224 if the cutouts are formed first.

In various embodiments, the additional cutout 224 may for example be located in a region encircled by the antenna 330. The cutout 224 may have a size corresponding to a fraction of an area (length×width) of the second polymer layer 104, for example up to about three quarters of the area, for example a quarter of the area or for example a fifth of the area. The cutout 224 may have any shape, for example rectangular or circular.

In various embodiments, the additional cutouts 224 may also be shaped as several smaller additional cutouts 224, for example several small circles 224 distributed over the region encircled by the antenna 330.

In various embodiments, the additional cutouts 224 may provide further regions through which the first polymer layer 102 and the third polymer layer 106 of the chip card substrate 100, after having been arranged underneath and above the second polymer layer 104, may form a coupling, for example a monolithically integrated structure. The coupling may be formed during lamination. In various embodiments, the additional cutouts 224 may thus serve to further increase the resilience of the chip card substrate 100 towards delamination.

In various embodiments, as shown in FIG. 3C, the cutouts 222 formed along the edge of the second polymer layer 104 may not be shaped rectangularly. The cutouts 222 may for example be elliptical or round.

Otherwise, features, materials, dimensions etc. may be similar to those described in connection with FIG. 3A and/or with FIG. 3B.

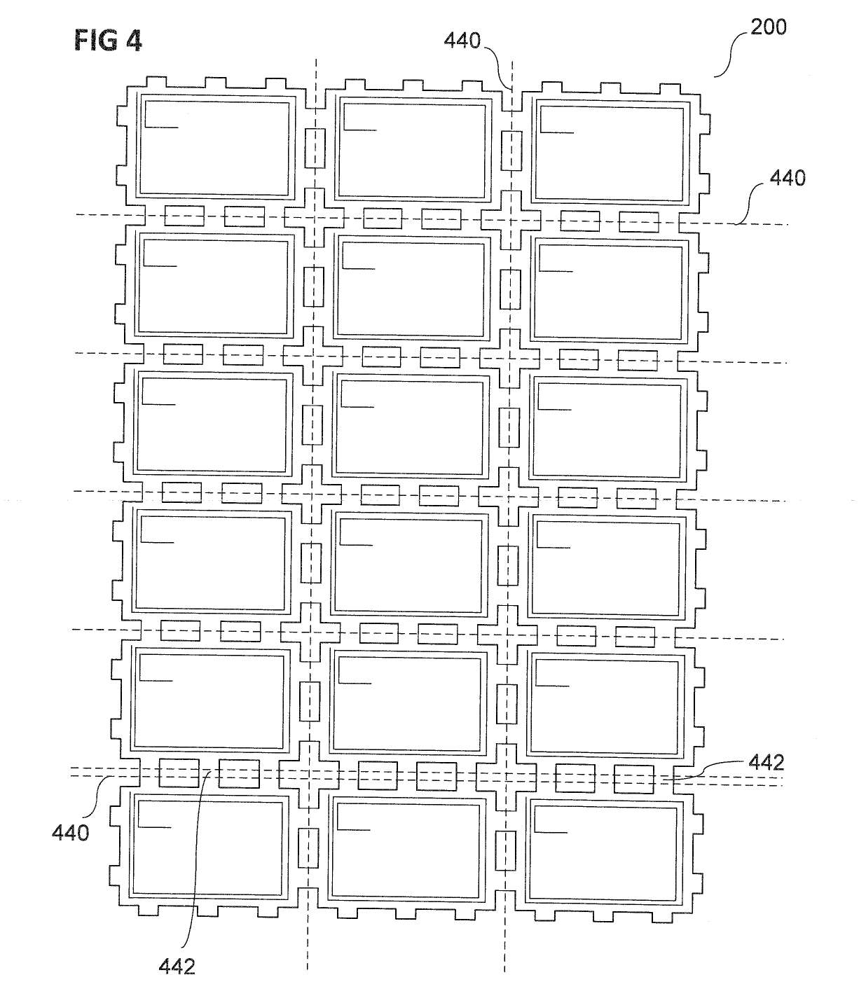

In various embodiments, round/elliptical cutouts 222, without sharp inner corners, may decrease a risk of a sheet of second polymer layers 104, like for example shown in FIG. 4, of tearing during handling of the sheet.

In various embodiments, as shown in FIG. 3D, the protrusions 210 may be arranged around the edge of the second polymer layer 104 irregularly. In other words, the cutouts 222 may have different lengths.

In various embodiments, the protrusions 210 of the second polymer layer 104 may have different shapes and sizes. For example, the lengths L_{P} and/or the widths W_{P} of the protrusions 210 may vary. For example, as shown in FIG. 3D, some protrusions 210 may have a smaller length L_{P} than other protrusions 210.

Otherwise, features, materials, dimensions etc. may be similar to those described in connection with FIG. 3A to FIG. 3B.

In various embodiments, one or more first parts of the edge of the second polymer layer 104 may have few or no protrusions 210. A larger than average fraction of the edge of the chip card substrate 100 to be formed that will be near the first part of the edge may thus have a monolithically integrated structure of the first polymer layer 102 and the third polymer layer 106 formed. For example, the first part of the edge of the second polymer layer 104 may have no protrusions 210, for example the first part may be located on the edge that will be located at an edge of the chip card to be formed that will frequently be inserted first into a chip reader. Additional protection from delamination starting on that edge may improve the overall resilience of the chip card towards delamination.

In various embodiments, second parts of the edge of the second polymer layer 104 may have more protrusions 210 to compensate for the lack/fewer number of protrusions 210 in the first part.

In various embodiments, the first part may for example be located near a location where the chip will be located in the chip card to be formed. Decreasing the number of protrusions 210 near the chip may decrease the risk of humidity, liquids, chemicals etc. entering the chip card (substrate) at the protrusion near the chip and reaching the chip.

In various embodiments, as shown in FIG. 4, a number of the plurality of cutouts 222, and lengths, widths and positions of the cutouts 222, and/or a number, length L_{P}, width W_{P} and position of the protrusions 210 may be chosen such that a sheet 200 of second polymer layers 104, also referred to as a polymer sheet 200, is formed. The sheet 200 of second polymer layers 104 may include, arranged in a plane, a plurality of second polymer layers 104 for a plurality of chip card substrates 100. In various embodiments, the second polymer layers 104 may be arranged in the polymer sheet 200 as a two-dimensional array. In other words, the sheet 200 of second polymer layers 104 may include or essentially consist of a two-dimensional array of second polymer layers 104.

In various embodiments, the polymer sheet 104 may include or essentially consist of polyethylene terephthalate. In various embodiments, the polymer sheet 104 may include or essentially consist of another material described in context with the second polymer layer 104.

In various embodiments, the cutouts 222 may be arranged on edges of the plurality of second polymer layers 104.

In various embodiments, the sheet 200 of second polymer layers 104 may be arranged between a first polymer layer 102 or a sheet of first polymer layers 102 and a third polymer layer 106 or a sheet of third polymer layers 106. In other words, a first polymer layer 102 or a sheet of first polymer layers 102 may be arranged underneath the sheet 200 of second polymer layers 104, and a third polymer layer 106 or a sheet of third polymer layers 106 may be arranged above the sheet 200 of second polymer layers 104. A distinction between a first/third polymer layer 102/106 or a sheet of first/third polymer layers 102/106, respectively, being arranged underneath/above may be made based on structures of the respective layers or sheets: If the polymer layer 102, 106 is structured across its plane, for example including a contact pad for electrically connecting a chip to the antenna 330, or a shielding structure to be arranged over the chip, a sheet of first/third polymer layers 102/106 matching the second polymer layers 104 in the sheet 200 of second polymer layers, i.e. matching with respect to a number and location of the polymer layers, may have to be arranged underneath/over the second polymer layer 104, whereas in a case of a horizontally unstructured first/third polymer layer 102/106, one polymer layer 102/104 may be considered as being arranged underneath/over the second polymer layer 104. In various embodiments, one of the first polymer layer 102 and the third polymer layer 106 may be a horizontally structured layer, and the other one of the first polymer layer and the third polymer layer may be a horizontally unstructured layer.

The first polymer layer(s) 102, the second polymer layers 104 of the layer 200 and the third polymer layer(s) 106 may be joined to form a plurality of chip card substrates 100 or chip cards. The first polymer layer(s) 102 and the third polymer layer(s) 106 may join through the cutouts 222. They may form monolithically integrated structures through the cutouts 222. The layers may be joined by means of lamination.

In various embodiments, the sheet 200 of second polymer layers 104 may not disintegrate during handling of the sheet 200. The plurality of second polymer layers 104 for a plurality of chip card substrates 100 may be connected with each other by means of the protrusions 210. In other words, the protrusions 210 of one of the second polymer layers 104 may be connected, for example physically connected, for example formed from one sheet together with an adjacent second polymer layer 104, by means of at least part of the protrusions 210 of the one second polymer layer 104 and at least part of the protrusions 210 of the adjacent second polymer layer 104.

In various embodiments, the protrusions 210 of adjacent second polymer layers 104 may be directly connected, i.e. where the protrusion 210 of the one second polymer layer 104 ends, the protrusion 210 of the adjacent second polymer layer starts.

In various embodiments, the protrusions 210 of adjacent second polymer layers 104 may be indirectly connected. For example, between the end of the protrusion 210 of the one second polymer layer 104 and the start of the protrusion 210 of the adjacent second polymer layer 104, an additional structure 442 of material from which the second polymer layers 104 are made may be present in the sheet 200, connecting the protrusion 210 of the one second polymer layer 104 to the protrusion 210 of the adjacent second polymer layer 104. In various embodiments, the additional structure 442 may furthermore extend towards and connect with adjacent additional structures 442.

In FIG. 4, dashed lines 440 may indicate separation lines, along which the sheet 200 of second polymer layers 104, for example after joining with the first polymer layer 102 and with the third polymer layer 106, for example after a lamination, may be separated, in other words singulated, into individual chip card substrates 100 or chip cards. The lines may not actually be drawn on the sheet 200 of second polymer layers 104. Single dashed lines 440 may indicate separation lines 440 for separating two chip card substrates 100. The protrusions 210 of the antenna carriers 104 of the two chip card substrates 100 may be directly connected. Double dashed lines 440, as shown between the bottom two rows of second polymer layers 104, may indicate separation lines 400 for separating the chip card substrate 100 from the additional structure.

In various embodiments, dimensions and locations of the protrusions 210, or of the cutouts 222, respectively, may be chosen such that the sheet 200 may be handled, for example for lamination, without one or more of the second polymer layers 104 tearing off inadvertently.

In various embodiments, the plurality of second polymer layers 104 arranged as the sheet 200 may be joined, for example laminated, during one joining, for example lamination, process. In other words, the plurality of second polymer layers 104 may be joined/laminated, for example joined/laminated with the first polymer layer(s) 102 and with the third polymer layer(s) 106, without a necessity to arrange each second polymer layer 104 of the plurality of second polymer layers 104 individually, for example individually on one of the first polymer layer 102 or the third polymer layer 106 or individually on a sheet of first polymer layers 102 or on a sheet of third polymer layers 106. Instead, the complete sheet 200 of second polymer layers 104 may be arranged between the sheet of first polymer layer(s) 102 and the sheet of third polymer layer(s) 106.

In other words, in various embodiments, the plurality of chip card substrates 100 may be formed in a common process by joining/laminating the three sheets of the first polymer layer(s) 102, the second polymer layers 104 and the third polymer layer(s) 106.

In various embodiments, the plurality of chip card substrates 100 may be processed thereafter in one sheet, for example during a separation, in other words singulation, into individual chip cars substrates 100. The separation, in other words singulation, may be performed along the separation lines 440 indicated on the second polymer layer 104. In various embodiments, the singulation may for example be performed by means of cutting, laser cutting, stamping, sawing and the like.

FIG. 5A shows a top view of a chip card 500 according to various embodiments, and FIG. 5B shows a cross sectional views of the chip card 500 of FIG. 5A along a line C-C′

In various embodiments, the chip card 500 may have been formed using any of the methods, structures, layers, parts, materials, parameters etc. described in context with the embodiments in the previous figures. The chip card 500 may be considered as a chip card substrate that may include a chip 550, and that may further include additional structures that may be used with the chip 550, for example additional contact structures or support structures, etc. The chip card substrate may include a first polymer layer 102, a second polymer layer 104, and a third polymer layer 106. They may correspond to first, second, and third polymer layers 102, 104 and 106, respectively, as described in the previous embodiments, and the second polymer layer may include cutouts 222 and protrusions 210 that may have a configuration as indicated here, or according to the other embodiments and specifications given in previous embodiments. In various embodiments, the chip card 500 may further include at least one antenna 330 and a contact pad 332 (which can only be seen in FIG. 5B). The antenna 330 and the contact pad 332 may be in accordance with the antenna/e 330 and the contact pad 332 described for previous embodiments.

According to various embodiments, the chip 550 may include at least one of an integrated circuit, an electronic circuit, a memory chip, an RFID chip (radio-frequency identification chip), or any other type of chip.

In various embodiments, the chip 550 may include a silicon bulk layer, e.g. a silicon substrate or a silicon wafer. The silicon bulk layer of the chip 550 may have a thickness in the range from about 10 μm to about 200 μm, e.g. in the range from about 20 μm to about 100 μm, e.g. in the range from about 30 μm to about 80 μm, e.g. in the range from about 50 μm, e.g. a thickness equal or less than 50 μm, e.g. 48 μm.

In various embodiments, the chip 550 may include at least one metallization layer.

In various embodiments, the chip 550 may be arranged on the same side of the antenna carrier 104 as the antenna 330. In various embodiments, the chip 550 may be arranged on the opposite side of the antenna carrier 104. In that case, the chip 550 may be electrically connected to the antenna 330 by means of a via, for example by means of a via through the antenna carrier 104, and by means of the contact pad 332.

In various embodiments, the chip 550 may include at least one chip contact. At least one of the at least one chip contact may provide an electrically conductive connection between the chip 550 and the at least one contact pad 332 arranged on the second polymer layer 104, as described above. In various embodiments, the chip 550 may include at least one chip contact. At least one of the at least one chip contact may provide the electrically conductive connection between the chip 550 and the antenna 330, e.g. via the at least one contact pad 332 arranged on the second polymer layer 104 as described above. In various embodiments, the chip 550 may include at least one chip contact 332. At least one of the at least one chip contact 332 may provide the electrically conductive connection between the chip 550 and an additional structure of the chip card 500, e.g. with an additional contact pad structure arranged on the back side of the second polymer layer 104.

In various embodiments, the chip 550 may have one or more chip contact pads. In case of more than one chip contact pad, the plurality of chip contact pads may be arranged in columns and lines, e.g. in two columns and two lines, e.g. in two columns and three lines, etc. In various embodiments, the chip contact pads may include or essentially consist of a conducting material, e.g. a metal, a metal alloy, a metallic material, a metallic compound, including at least one of Cu, Al, Au, Ag, Pt, Ti, Ni, Sn, Zn, Pb, or any non-metal electrically conducting material, e.g. graphite. The chip contact pad(s) may be electrically connected to the chip by one or more of the at least one chip contacts 332. The chip contact pad(s) may have a lateral extension in the range of about 10 μm to about 1000 μm, e.g. about 200 μm to about 800 μm, e.g. about 300 μm to about 700 μm, e.g. about 400 μm to about 600 μm, e.g. about 500 μm. In various embodiments, the chip contact pads may be exposed, i.e. they may be facing towards an outside of the chip card 500, and the polymer layer, e.g. the third polymer layer as shown in FIG. 5B, or more generally one of the first polymer layer 102 and the third polymer layer 106 that would be arranged to cover the chip 550, may have a cutout formed such that the chip contact pads are at least partially not covered by the polymer layer 102 or 106, such that the chip 550 may be electrically connected to a peripheral structure, e.g. to a data reader device, a programming device, and the like.

In various embodiments, the chip 550 may be attached to the antenna carrier 104 e.g. by use of an adhesive, e.g. a glue, by fusing, molding or soldering.

In various embodiments, the chip 550 may include a chip support structure in which the functional chip itself (i.e. the programmed/programmable semiconductor device), the chip contact pads, etc. are mounted. According to various embodiments, the glue structure or the solder structure may have a thickness in the range of about 1 μm to about 100 μm, e.g. about 10 μm to about 80 μm, e.g. about 30 μm to about 60 μm, e.g. about 50 μm, e.g. in a thickness equal or less than 50 μm.

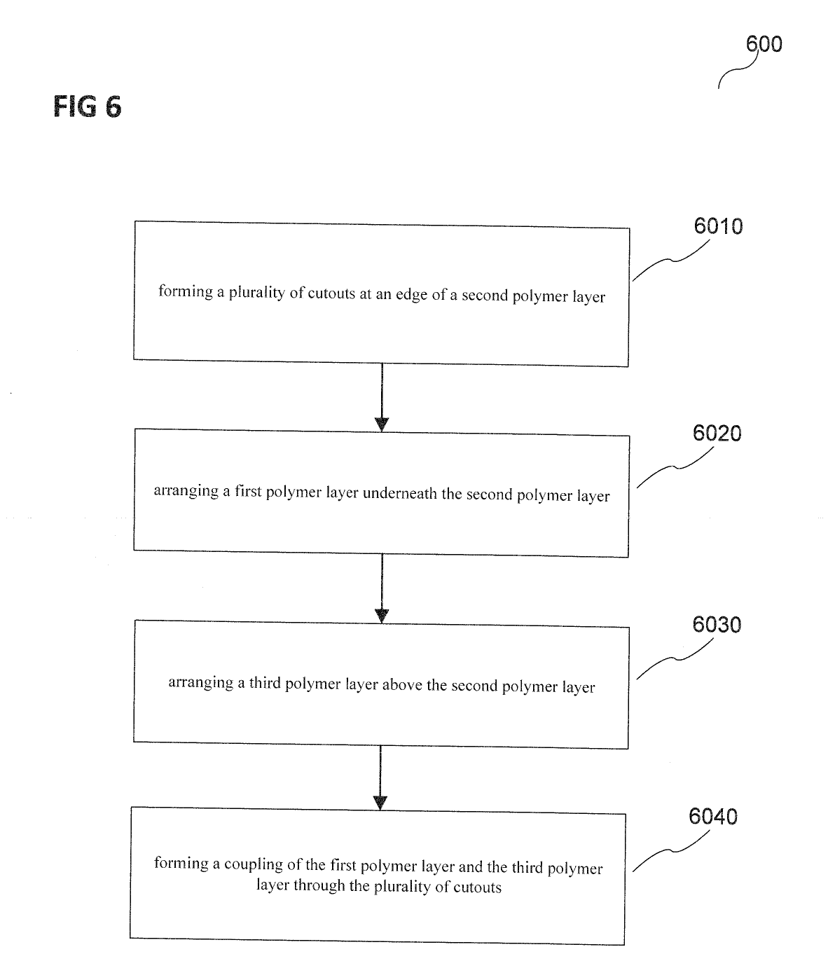

FIG. 6 shows a process flow 600 for a method of forming a chip card substrate.

A method of forming a chip card substrate may include forming a plurality of cutouts at an edge of a second polymer layer (in 6010). It may further include arranging a first polymer layer underneath the second polymer layer (in 6020), arranging a third polymer layer above the second polymer layer (in 6030), and forming a coupling of the first polymer layer and the third polymer layer through the plurality of cutouts (in 6040).

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A polymer sheet for a plurality of chip card substrates, including
a plurality of second polymer layers arranged in a two-dimensional array in a plane of the polymer sheet; and
a plurality of cutouts,
wherein the plurality of cutouts is arranged at edges of the plurality of second polymer layers.

2. The polymer sheet of claim 1,
wherein the plurality of second polymer layers comprises polyethylene terephthalate.
